(19) United States
(12) Patent Application Publication
(10) Pub. No.: US 2009/0110915 A1
(43) Pub. Date: Apr. 30, 2009

(54) UNIVERSAL NUCLEATION LAYER/DIFFUSION BARRIER FOR ION BEAM ASSISTED DEPOSITION

(75) Inventor: Alp T. FINDIKOGLU, Los Alamos, NM (US)

Correspondence Address: HUSCH BLACKWELL SANDERS LLP, 720 OLIVE STREET, SUITE 2400, ST. LOUIS, MO, 63101, US

(73) Assignee: LOS ALAMOS NATIONAL SECURITY, LLC, Los Alamos, NM (US)

(21) Appl. No.: 11/923,232

(22) Filed: Oct. 24, 2007

(51) Int. Cl. C23C 14/14; B05D 1/36; B32B 9/04

(52) U.S. Cl. 428/336; 427/402; 427/419.2; 427/419.7; 427/529; 428/447

(57) ABSTRACT

A method for a new universal nucleation-layer/diffusion barrier, which is based on amorphous films of Si—O and Si—N for ion-beam-assisted deposition (IBAD) process. Unlike other nucleation layers that were used in the past, this process works on a variety of substrates (glass, Hastelloy tape, Cu), with varying surface roughness, and with a wide range of thickness. In addition, this new material system of Si—O (and Si—N) is ideally suited for oxide (and nitride) based multilayer stacks. As importantly, the flexibility in nucleation layer thickness allows the nucleation layer to be an effective diffusion barrier, and to be grown at room temperature, while the IBAD layer and subsequent epitaxial layers can be grown much thinner than usual.

### STATEMENT REGARDING FEDERAL RIGHTS

This invention was made with government support under Contract No. DE-AC52-06NA25396 awarded by the U.S. Department of Energy. The government has certain rights in the invention.

### BACKGROUND OF INVENTION

This invention relates generally to nucleation layers/diffusion barriers and, more particularly, to ion beam assisted deposition.

In many technical thin film deposition processes, ion beam assisted deposition (IBAD) is known to have beneficial effects on the properties of the films. In most of these applications the fast generation of coatings, optical layers, etc., with thickness in the range of microns is at the center of interest. By contrast, when growing epitaxial films in the range of atomic mono layers the layer-by-layer growth mode is most often desired in order to produce films of optimum smoothness. Ion beam assisted deposition techniques are used in the field of integrated semiconductor fabrication for substrate preparation. These techniques are of interest because of the capability of ion beam deposition to grow thin film semiconductor layers. The kinetic energy of the ions can enhance the likelihood of epitaxial growth. Many prior art ion beam deposition techniques utilize sputtering.

The type of interface formed during deposition depends on substrate surface morphology, contamination, chemical interactions and the energy and flux of arriving particles and the nucleation behavior of depositing atoms. When atoms impinge on a surface, they do not immediately become bound but lose energy to the surface and move about until they are captured at a suitable sight during film growth. Adatoms will condense into stable nuclei and the spacing and size of these nuclei will determine the interfacial surface structure of a coating. A strong substrate/coating atom interaction will result in a low adatom mobility and a high density of nuclei, whereas a weak interaction will result in a more widely spaced nuclei. The nuclei can then grow to form a continuous film during which the rate at which lateral spreading of the nuclei occurs will influence the effective porosity at the interface as well as the nucleation density. The nucleation density and size of the individual nuclei will determine the effective contact area between coating and substrate which can be directly related to adhesion. In general, an increase in nucleation density is desirable if the adhesion of a film is to be improved.

Substrate preparation techniques have been developed to increase the nucleation density and hence coating density and adhesion. The nucleation density can be increased by ion bombardment and hence reducing the gas pressure in sputtering systems. Ion bombardment is a method utilized to introduce a chosen atomic species into a material. The resulting depth concentration profile of implanted atoms can be calculated for most projectile target combinations from well established theoretical models. Incident ions transfer a significant amount of energy into the substrate resulting in the displacement of target atoms. As a consequence, there is a probability of atomic ejection or sputtering from the target surface and an equilibrium condition may be reached whereas many atoms are removed by sputtering as are replenished by implantation.

In such conditions, the depth distribution of implanted atoms present a maximum at the surface and falls off over a distance comparable to the initial range. This technique allows the controlled introduction of almost any additive at a limited depth without the necessity of elevated temperatures. The limited depth of the additive with this process, however, can limit the effective use of this substrate preparation method, because substrate surfaces that have a certain roughness may be rendered useless due to the limited depth capability and the inability to smooth over rough surfaces.

If a thick coating applied on a substrate is bombarded with energetic ions which pass through into the substrate, it is possible to bring about a progressive intermixing in which the atoms are transported either by rapid coalitional affects or by various mechanisms of radiation enhanced diffusion. The end result is a non-equilibrium stage which resembles in many ways that produced by direct ion bombardment.

Thin films and coatings of material can be deposited on various substrates via the condensation of vapors on the substrate surface and can be maintained at a temperature of nearly room temperature. The element or compound is evaporated from a source by either a heated or high temperature evaporation process or subjected to ion bombardment of sufficient high energy to result in a sputtering process. The energy required for production and transfer of vapor species from a condensed source material to the substrate is provided by heat transfer in evaporation and by momentum transfer and sputtering.

Ion plating, arc deposition and ion beam deposition or physical vapor deposition processes can be used for the production of nitride, carbide and oxide coatings. These coatings can provide wear protection, surface preparation and optical interference coatings. Common features of these processes are the incorporation of reactive gas ions into the growing film and ion bombardment of the substrates before and during deposition. Ion impact facilitates temperatures inferior to those comparable to chemical vapor deposition processes and ion bombardment treated surfaces can have higher strength, higher density and higher elasticity.

These substrate preparation processes utilizing ion beam assisted deposition can be utilized to prepare a substrate for semiconductor use. These substrate surface treatments provide a nucleation layer and/or a diffusion barrier such that an epitaxial layer can be applied for a semi conductor device. However, previous methods have not allowed for a sufficient layer to be applied having a sufficient thickness to correct for any substrates having a rough surface or for substrates that are amorphous such as glass. Therefore, this limitation has prevented the effective use of the IBAD process on amorphous substrates or substrates that have a rougher surface. Therefore, there is a need to have an improved process that allows for application of a nucleation layer/diffusion barrier for substrates that are amorphous or that do not have a sufficiently smooth surface

There have been a number of attempts to align the axis of the crystals deposited on the surface of such substrate bases as plates and metal tapes. One such method involves depositing thin films on single crystal substrate bases having a similar crystal structure as the oxide superconductors, such as MgO and SrTiO₃, with the use of such thin film forming techniques as sputtering.

The use of single crystal materials such as MgO and SrTiO₃ as a substrate and sputtering crystal thereon enables the deposited crystals to duplicate the highly oriented single crystal structure of the substrate material. Oxide superconductors thus produced have exhibited excellent Jc of several hundred thousand to several million amperes/cm² (A/cm²).

However, to utilize oxide superconductors as electrical conductors, it is necessary to form the crystal on the surface of an extending object such as a tape substrate. However, when a superconductor crystal is formed on the surface of a metal tape, for example, the deposited crystal layer can hardly be expected to have an oriented structure because such tapes are polycrystalline and also possess a crystal structure different from the deposited oxide superconductor. Further, thermal processing accompanying the film forming process promotes inter-diffusion of elements between the oxide superconductor and the substrate material, leading to degradation of the oxide material, and the resulting deterioration in the superconducting properties.

The conventional approach, therefore, has been to utilize an intermediate layer on top of the metal tape substrate, such as MgO and SrTiO₃, for example, and to deposit the oxide material on top of the intermediate layer. However, oxide superconducting films, formed by sputtering on top of such an intermediate layer, exhibited considerably lower Jc values (for example, several thousand to several tens of thousands A/cm²) compared with those formed on top of a single crystal layer.

Further efforts have resulted in development of a process, coupled with pulsed laser deposition (PLD) YBCO, that has produced meter lengths of superconducting wire with critical current densities over 1 MA/cm² and critical currents over 100 A. Despite these results, one criticism of the IBAD-YSZ process has been that the time required to deposit the material with sufficient in-plane texture for high quality YBCO is too long. In order to develop texture, YSZ requires a thickness of between 0.5 and 1 micrometer (μm) to achieve a Δφ (or full width at half maximum of the φ-scan peak) better than 12°. Reported IBAD deposition times have ranged from about one to twelve hours per meter of tape. Thus, the viability of this process has been questionable for cost efficient, industrial fabrication.

Subsequently, it has been shown that magnesium oxide (MgO) can be deposited with the IBAD process and produce a thin film with in-plane texture comparable to YSZ that was only 10 nanometers (nm) thick. This translates to a process about 100 times faster than IBAD YSZ. This process has been applied to further development in the preparation of FITS coated conductors. For example, short length samples (less than about 4 cm long) using IBAD MgO templates have been produced with J_{c}s over 1 MA/cm² (77 K) for>1.5 μm thick YBCO films.

However, IBAD MgO still has some drawbacks that detract from its viability as a template layer for long length processing of coated conductors. The two most detrimental limitations are (1) the degradation of in-plane texture as IBAD MgO film thickness increases beyond a critical thickness of 10 nm; and, (2) the necessity to deposit IBAD MgO films on very smooth (<2 nm rms) substrates. A concern for conventional IBAD processing of MgO has been the need for ultra-smooth (<2 nm root mean square (RMS)) surfaces to improve in-plane texture. It had been previously demonstrated that decreased surface roughness decreased in-plane misorientation and increased subsequent YBCO J_{c}. While just increasing the thickness of the IBAD MgO layer would seem to overcome this limitation in the IBAD process, conventional IBAD MgO texture degrades as the thickness is increased beyond about 10 nm.

### SUMMARY OF THE INVENTION

The invention is a new universal nucleation-layer/diffusion barrier, which is based on amorphous films of Si—O and Si—N for an ion-beam-assisted deposition (IBAD) process. Unlike other nucleation layers that were used in the past, this process works on a variety of substrates (glass, Hastelloy tape, Cu), with varying surface roughness, and with a wide range of thickness. In addition, this new material system of Si—O (and Si—N) is ideally suited for oxide (and nitride) based multilayer stacks. As importantly, the flexibility in nucleation layer thickness allows the nucleation layer to be adjusted to be an effective diffusion barrier, and to be grown at room temperature, while the IBAD layer and subsequent epitaxial layers can be grown much thinner than usual.

This invention can have commercial applications for photovoltaics and flat panel displays when combined with Si films; and coated conductor tapes and cables when combined with high-temperature superconductors. The growth of nucleation layers of Si—O and Si—N for IBAD MgO and IBAD TiN processes provide a technique that is flexible in that it allows for substrate choice, in addition to wide range of substrate surface roughness, nucleation layer thickness and homo-epitaxial layer thickness. The invention can also provide better performance for IBAD applications such as for example Aligned Crystalline Silicon films for photovoltaics and electronics, and superconductor films for coated conductor applications.

One embodiment of the present invention is a process to achieve an IBAD MgO on SiO nucleation layer/diffusion barrier comprising the steps of:

Clean a substrate with a 40 mA/600 eV reactive ion beam (with 5/5/6 sccm of Ar/Ar/O₂ for source/neutralizer/source, respectively) for 1-5 minutes. Deposit a 20-240 nm of amorphous SiO at ˜0.2 nm/s with the assistance of a reactive ion beam (40 mA/1000 eV, 5/5/6 sccm of Ar/Ar/O₂). Deposit a 3-6 nm of biaxially-oriented MgO layer at 0.20 nm/s with the assistance of a reactive ion beam (40 mA/10 eV, 5/5/6 sccm of Ar/Ar/O₂).

An alternative method is to clean a substrate with a 40 mA/600 eV reactive ion beam (with 5/5/6 sccm of Ar/Ar/O₂ for source/neutralizer/source, respectively) for 1-5 minutes. Deposit a 10-160 nm of amorphous Si—N at ˜0.2 nm/s with the assistance of a reactive ion beam (40 mA/1000 eV, 5/5/6 sccm of Ar/Ar/N₂). Deposit a 5-8 nm of biaxially-oriented TiN layer at 0.2 nm/s with the assistance of a reactive ion beam (40 mA/1000 eV, 5/5/6 sccm of Ar/Ar/N₂). Also, homo-epitaxial and hetero-epitaxial layers can be grown on these IBAD-MgO and IBAD-TiN layers following standard process conditions.

The present invention uses the IBAD process, in essence, to transform the surface of almost any substrate into a near single crystalline (i.e., crystalline quality of the film approaching that of single crystals) template, on which subsequent epitaxial layers can be grown. It allows use of relatively inexpensive substrates like metal tapes or glass for epitaxial growth of high quality materials. There are three specific elements of the IBAD process. The first is the use of a nucleation layer on these inexpensive substrates that facilitates the IBAD layer growth. Then, the IBAD layer is grown on the nucleation layer. It is this critical process, the IBAD layer growth, which in essence transforms the non-single-crystalline surface into near-single-crystalline surface (i.e., crystalline quality of the film approaches that of single crystals). The third step is the growth of epitaxial layer on the IBAD layer, so all three layers, nucleation layer, IBAD layer and epitaxial layer, form the buffer stack. In addition, in most conventional uses of the IBAD process, a separate diffusion barrier layer is used between the substrate and the nucleation layer.

This buffer stack, once it is complete, can be ready to be used by, for example, high temperature superconductor applications, where a high quality superconducting film is epitaxially grown on top of the buffer stack. Similarly, a certain buffer stack could be arranged to allow epitaxial growth of high quality semiconductor films. Other functional materials such as ferroelectric, ferromagnetic, piezoelectric, transparent, conducting, insulating, semiconducting, superconducting layers, and their combinations, can also be grown epitaxially on the buffer stack depending on the application.

This invention more specifically relates to the nucleation layer, that is based on silicon-oxide or silicon-nitride (or, silicon-oxynitride), in the first stage of using this ion beam assisted deposition process. This nucleation layer is an improvement over the conventional nucleation layer based on amorphous/nanocrystalline yttria. The conventional nucleation layer material yttria needs to be of a certain thickness (typically, between 3 and 8 nm) and of certain crystalline characteristics (amorphous/nanocrystalline) for it to be effective for the IBAD process. In particular, special attention needs to be given to the growth of yttria nucleation layer to avoid polycrystalline texture formation, in which case the IBAD process does not work. On the other hand, this invention, by providing a new and more robust material system, a wider window of process parameters, and a wider range of available thicknesses, improves on the prior art in many aspects. It allows the process to be used on materials that were not capable of being utilized before. In using this silicon oxide or silicon nitrite (or, silicon-oxynitride) layer, the IBAD process can be performed on not-as-well polished copper, stainless steel, Ni-alloy, etc. So it's an improvement over prior art in the sense that now the same process can be performed on a wider range of substrates.

Therefore, relatively thick layers of silicon oxide can be applied, thereby fine tuning diffusion requirements using just a silicon oxide layer instead of having to have a separate diffusion layer plus a certain thickness nucleation layer, now we can have a silicon oxide (or, silicon nitride or silicon-oxynitride) layer that with the right thickness can work as a perfect nucleation layer for IBAD process as well as work as an effective diffusion barrier for the subsequent epitaxial growth of other layers or other process that the structure will be exposed to. It allows use of the nucleation layer as a more effective diffusion barrier.

The present invention allows use of relatively thick layers of this amorphous silicon-oxide (or, silicon-nitride) film material without having a future polycrystalline problem, allowing for use of substrates that have rougher surfaces, because the process can coat the surface having the rough features with the smooth layer that is a relatively thick layer or the deposition of the nucleation layer. This allows for the use of a cheaper process for the substrate preparation. For example, this process can be utilized for superconductor work, because prior to the present invention, the use of metal tape for a similar process required certain surface smoothness for the process to work because previous nucleation layer methods did not allow for thicker layers because it didn't work for IBAD.

The present invention's use of amorphous silicon oxide or nitride film allows the nucleation layer to be as thick as required to make it as smooth as required and then use the IBAD process. So the substrate preparation can be cheaper now using this nucleation layer. The growth of nucleation layers of Si—O and Si—N for IBAD MgO and TiN processes respectively are extremely robust in terms of substrate choice, substrate surface roughness, nucleation layer thickness and homo-epitaxial layer thickness. Similar IBAD processes based on other face-centered cubic oxide and nitride materials could also use this nucleation layer. The present invention promises to enable superior performance in applications where IBAD is currently used, such as Aligned Crystalline Silicon films for photovoltaics and electronics applications, and High-Temperature Superconductor films for coated conductor applications. Unlike other nucleation layers that were used in the past, this process works on a variety of substrates (glass, stainless steel, Hastelloy tape, Cu), with varying surface roughness, and with a wide range of thickness. In addition, this system of Si—O (and Si—N and Si—O—N) is ideally suited for oxide and nitride based multilayer stacks. Also the flexibility in a nucleation layer thickness allows the nucleation layer to be an effective barrier, and to be grown at room temperature, while the IBAD layer and subsequent layers can be grown much thinner.

These and other advantageous features of the present invention will be in part apparent and in part pointed out herein below.

### BRIEF DESCRIPTION OF THE DRAWINGS

For a better understanding of the present invention, reference may be made to the accompanying drawings in which:

FIG. 1 is an illustration of the components of an IBAD stack representative of the present invention.

While the invention is susceptible to various modifications and alternative forms, specific embodiments thereof are shown by way of example in the drawings and will herein be described in detail. It should be understood, however, that the drawings and detailed description presented herein are not intended to limit the invention to the particular embodiment disclosed, but on the contrary, the intention is to cover all modifications, equivalents, and alternatives falling within the spirit and scope of the present invention as defined by the appended claims.

### DETAILED DESCRIPTION OF INVENTION

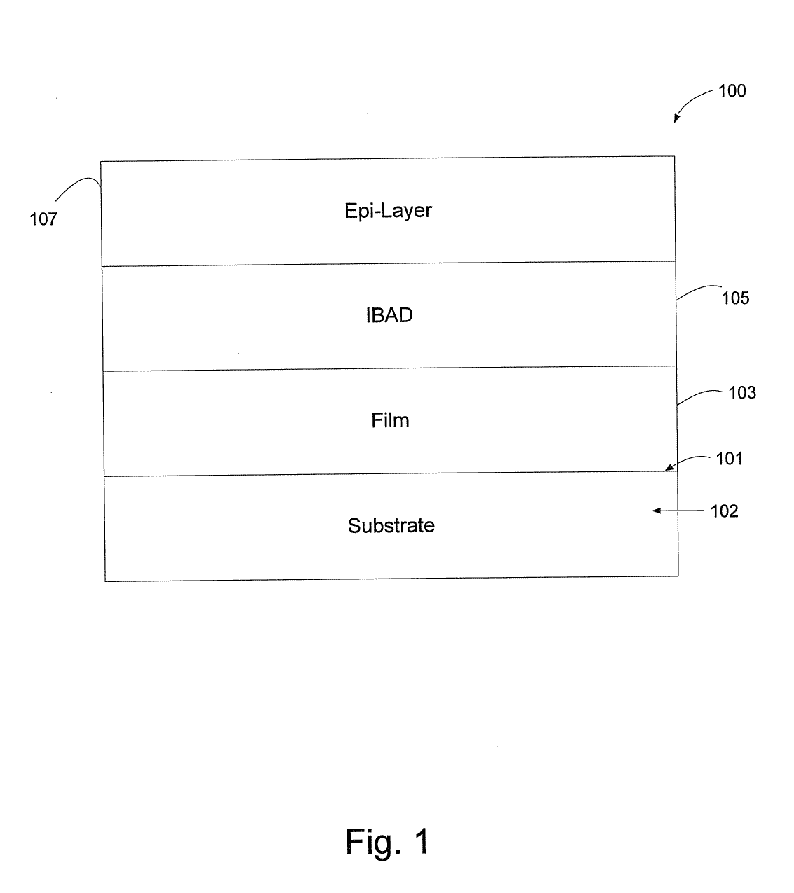

According to the embodiment(s) of the present invention, various views are illustrated in FIG. 1 and like reference numerals are being used consistently throughout to refer to like and corresponding parts of the invention for all of the various views and figures of the drawing. Also, please note that the first digit(s) of the reference number for a given item or part of the invention should correspond to the Fig. number in which the item or part is first identified.

One embodiment of the present invention comprising the steps of cleaning a substrate with a 40 mA/600 eV reactive ion beam with a volumetric flow rate of 5/5/6 sccm of Ar/Ar/O₂ for source/neutralizer/source, respectively for 1 to 5 minutes; depositing 20 to 240 nm of amorphous Si—O at ˜0.2 nm/s with the assistance of the reactive ion beam; and depositing 3 to 6 nm of biaxially-oriented IBAD MgO layer at ˜0.2 nm/s with the assistance of the reactive or inert ion beam using standard conditions and growing homo-epitaxial or hetero-epitaxial layers using standard conditions thereon, teaches a novel method for preparation of a substrate for superconductor or semiconductor applications.

Yet another embodiment of the present invention is a method comprising the steps of cleaning a substrate with a 40 mA/600 eV reactive ion beam with a volumetric flow rate of 5/5/6 sccm of Ar/Ar/N₂ for source/neutralizer/source, respectively for 1 to 5 minutes; depositing 10 to 160 nm of amorphous Si—N at ˜0.2 nm/s with the assistance of the reactive ion beam; and depositing 5 to 8 nm of biaxially oriented TiN layer at ˜0.18 nm/s with the assistance of the reactive ion beam using standard process conditions and growing homo-epitaxial or hetero-epitaxial layers using standard conditions thereon, teaches a novel method for preparation of a substrate for superconductor or semiconductor applications.

The details of the invention and various embodiments can be better understood by referring to the figures of the drawing. Referring to the drawing, FIG. 1 is an illustration of an IBAD stack 100 formed by the present method. Forming a nucleation layer enables crystallographic texturing of the template layer 106. The nucleation layer 104 is formed by treating the surface 101 of a substrate 102 using ion bombardment while depositing a Si—O (or, Si—N or Si—O—N) film 103. The surface of the substrate can be bombarded with Ar⁺ ions, or Ar⁺ and O⁺ ions for about approximately 1 to 5 minutes using ion beams having energies in the range of about approximately 600 eV to 1000 eV and an ion current in the range of about approximately 40 mA to 200 mA. In an alternative embodiment, the substrate can be bombarded with Ar⁺, or Ar⁺ and N⁺ ions, while depositing a Si—N film. In another alternative embodiment, the substrate can be bombarded with Ar⁺, or Ar⁺ and N⁺ ions, or Ar⁺ and O⁺ and N⁺ ions while depositing a Si—O—N film. Deposition of about approximately 20 to 240 nm of amorphous Si—O or Si—N (or, Si—O—N) at ˜0.2 nm/s with the assistance of the ion beam is performed. On this nucleation layer, a standard IBAD layer growth is performed. For example, a deposition of about approximately 3 to 6 nm of biaxially oriented MgO or TiN layer at 0.2 nm/s with the assistance of the inert or reactive ion beam is performed. With either embodiment a homo-epitaxial and/or a hetero-epitaxial layer 107 can be grown on the IBAD stack.

In an alternative embodiment, the nucleation layer 104 can be formed by treating the surface of a substrate 102 using ion bombardment. The surface of the substrate can be bombarded with Ar⁺ ions and N⁺ ions for about approximately 1 to 5 minutes using ion beams having energies in the range of about approximately 600 eV to 1000 eV and an ion current in the range of about approximately 40 mA to 200 mA. In an alternative embodiment, the substrate can be bombarded with Ar⁺ and O⁺ ions.

The ability to grow highly-crystalline epitaxial films on metal sheets or glass plates, with associated improved electrical and optical properties, or on substrates having rougher surfaces could especially be useful in applications where devices with superior performance and added functionalities are needed. Amorphous glass substrates, due to their transparency, durability, and chemical robustness, are of particular interest for use in applications such as sensors, photovoltaics, and displays. Polycrystalline metal substrates are also of particular interest for use in applications such as sensors, photovoltaics, and displays.

Previously to achieve highly crystalline film growth on such an amorphous or polycrystalline substrate, the process involved first growing an ion-beam-assisted deposition (IBAD) textured buffer layer on a conventional yttria nucleation layer. However the conventional yttria nucleation layer cannot be grown in a wide range of thicknesses and process conditions. Therefore, one needs a relatively smooth surface for the substrate. Also, one needs a separate diffusion barrier material, such as amorphous aluminum-oxide, since the conventional yttria nucleation layer is not a robust diffusion barrier.

The present invention allows use of relatively thick layers of the nucleation layer material, Si—O or Si—N or Si—O—N, without having a polycrystallinity problem, allowing for use of substrates that have rougher surfaces, because the process can coat the surface having the rough features with the smooth layer that is a relatively thick layer or the deposition of the nucleation layer. This allows use of a cheaper process for the substrate preparation. For example, this process can be utilized for superconductor work, because prior to the present invention the use of metal tape required certain surface smoothness for the process to work because previous nucleation layer methods did not allow for thicker layers because it didn't work for IBAD. The present inventions use of silicon oxide or silicon nitride or silicon oxynitride allows the nucleation layer to be as thick as required to make it as smooth as required and then use the IBAD process. Also, by having a relatively thick nucleation layer, one can combine the requirements of nucleation layer as well as the diffusion barrier in one layer. So the substrate preparation can be cheaper now using this nucleation layer.

The nucleation layer can be deposited by electron beam evaporation as well with or without ion beam assistance, and the thickness can be between about approximately 5 nm and about approximately 500 nm. Other deposition methods known in the art, such as sputtering, electron beam evaporation, metal-organic deposition, metal-organic chemical vapor deposition, chemical vapor deposition, polymer assisted deposition, liquid phase epitaxy, solid phase crystallization, and laser ablation may also be used. The increased thickness can help smooth any roughness on the surface of the substrate and provides a more effective diffusion barrier between the substrate and the IBAD layer and the subsequently grown epitaxial layers.

The various IBAD nucleation layer/diffusion barrier examples shown above illustrate a novel method for preparation of highly crystalline templates on non-single-crystalline substrates. A user of the present invention may choose any of the above embodiments, or an equivalent thereof, depending upon the desired application. In this regard, it is recognized that various forms of the subject invention could be utilized without departing from the spirit and scope of the present invention.

As is evident from the foregoing description, certain aspects of the present invention are not limited by the particular details of the examples illustrated herein, and it is therefore contemplated that other modifications and applications, or equivalents thereof, will occur to those skilled in the art. It is accordingly intended that the claims shall cover all such modifications and applications that do not depart from the sprit and scope of the present invention.

Other aspects, objects and advantages of the present invention can be obtained from a study of the drawings, the disclosure and the appended claims.

What is claimed is:

1. A method for preparing a highly crystalline template structure for growth of oriented layers thereon comprising the steps of:
providing a substrate;
depositing an amorphous silicon film selected from a group consisting of silicon oxide, silicon nitride and silicon oxynitride on the surface of the substrate forming a nucleation layer having a thickness sufficient to smooth over surface roughness and act as an effective diffusion barrier;
depositing a highly crystalline template having a biaxially oriented texture transforming the surface into a highly oriented surface.

2. The method for preparing a template structure as recited in claim 1, where the substrate provided is selected from the group consisting of glass, stainless steel, Ni, Ni-alloy, Fe-alloy, Hastelloy, Cu, and polyimide.

3. The method for preparing a template structure as recited in claim 1, wherein the highly crystalline template is deposited by ion beam assisted deposition.

4. The method for preparing a template structure as recited in claim 3, where the ion beam in ion beam assisted deposition comprises an inert gas selected from a group consisting of Ar, He, Ne, and Kr.

5. The method for preparing a template structure as recited in claim 4, where the ion beam in ion beam assisted deposition comprises, in addition to an inert gas, a reactive gas selected from a group consisting of O and N.

6. The method for preparing a template structure as recited in claim 5, where the nucleation layer thickness is about approximately 5 to 500 nm in thickness.

7. The method for preparing a template structure as recited in claim 1, where said highly crystalline template having a biaxially oriented texture is selected from a group consisting of MgO and TiN.

8. The method for preparing a template structure as recited in claim 7, where said highly crystalline template has a thickness of about approximately 3 to 8 nm.

9. The method for preparing a template structure as recited in claim 1, where said highly crystalline template having a biaxially oriented texture is selected from a group consisting of cubic materials, such as metal oxides consisting of magnesium oxide, calcium oxide, strontium oxide, barium oxide, titanium oxide, zirconium oxide, vanadium oxide, niobium oxide, tantalum oxide, chromium oxide, manganese oxide, iron oxide, cobalt oxide, nickel oxide, cadmium oxide, scandium oxide, lanthanum oxide, cerium oxide, neodymium oxide, samarium oxide, europium oxide, ytterbium oxide, and combinations thereof.

10. The method for preparing a template structure as recited in claim 1, where said highly crystalline template having a biaxially oriented texture is selected from a group of metal nitrides consisting of titanium nitride, nickel nitride, tantalum nitride, aluminum nitride, chromium nitride, silicon nitride, gallium nitride, carbon nitride, and combinations thereof.

11. A template structure where said structure comprising:
a substrate;
an amorphous silicon film selected from a group consisting of silicon oxide, silicon nitride and silicon oxynitride deposited on the substrate surface forming a nucleation layer having a thickness sufficient to smooth over surface roughness and act as an effective diffusion barrier;
a highly crystalline template having a biaxially oriented texture transforming the surface into a highly oriented surface.

12. The template structure as recited in claim 11, where the substrate provided is selected from the group consisting of glass, stainless steel, Ni , Ni-alloy, Fe-alloy, Hastelloy, Cu, and polyimide.

13. The template structure as recited in claim 11, wherein the highly crystalline template is deposited by ion beam assisted deposition.

14. The template structure as recited in claim 11, where the nucleation layer is selected from the group consisting of Si-oxides, Si—Nitrides, and Si-oxynitrides.

15. The template structure as recited in claim 14, where the nucleation layer thickness is about approximately 5 to 500 nm in thickness.

16. The template structure as recited in claim 11, where said highly crystalline template having a biaxially oriented texture is selected from a group consisting of MgO and TiN.

17. The template structure as recited in claim 16, where said highly crystalline template has a thickness of about approximately 3 to 8 nm.

18. The method for preparing a template structure as recited in claim 11, where said highly crystalline template having a biaxially oriented texture is selected from a group of cubic materials, such as metal oxides consisting of magnesium oxide, calcium oxide, strontium oxide, barium oxide, titanium oxide, zirconium oxide, vanadium oxide, niobium oxide, tantalum oxide, chromium oxide, manganese oxide, iron oxide, cobalt oxide, nickel oxide, cadmium oxide, scandium oxide, lanthanum oxide, cerium oxide, neodymium oxide, samarium oxide, europium oxide, ytterbium oxide, and combinations thereof.

19. The method for preparing a template structure as recited in claim 11, where said highly crystalline template having a biaxially oriented texture is selected from a group of metal nitrides consisting of titanium nitride, nickel nitride, tantalum nitride, aluminum nitride, chromium nitride, silicon nitride, gallium nitride, carbon nitride, and combinations thereof.
